(19) United States
(12) Patent Application Publication
(10) Pub. No.: US 2013/0056706 A1
(43) Pub. Date: Mar. 7, 2013

(54) QUANTUM DOT LED LIGHT SYSTEM AND METHOD

(71) Applicant: Kevin C. Baxter, Glendale, CA (US)

(72) Inventor: Kevin C. Baxter, Glendale, CA (US)

(21) Appl. No.: 13/603,266

(22) Filed: Sep. 4, 2012

Related U.S. Application Data
(60) Provisional application No. 61/530,209, filed on Sep. 1, 2011.

(51) Int. Cl. H01L 33/06; H01L 33/08

(52) U.S. Cl. 257/13; 438/29; 257/E33.008; 257/E33.067

(57) ABSTRACT

The present disclosure provides methods of using quantum dots or Q dots or a similar nanocrystal to transfer, for example, excess LED light energy in the blue band to the red band where such LEDs tend to be deficient. This approach would balance the overall spectrum of the LED without a corresponding loss in brightness as would be the case where the light from the LED was passed through a conventional filter. The Q dots could be applied to the lens portion of the LED after the high temperature processes are completed or coated to a clear filter to be placed in the LED light path.

### CROSS REFERENCE TO RELATED APPLICATION

This application claims the benefit of U.S. Provisional Patent Application Ser. No. 61/530,209 filed on Sep. 1, 2012 and incorporates said provisional application by reference into this disclosure as if fully set out at this point.

### FIELD OF THE INVENTION

The field of the present invention relates to lighting fixtures and systems as may be used in photography, film, television, video, motion picture and other applications.

### BACKGROUND OF THE INVENTION

Lighting systems are an integral part of the film, television, video, motion picture, and photography industries. Proper illumination is necessary when filming movies, television shows, or commercials, when shooting video clips, or when taking still photographs, whether such activities are carried out indoors or outdoors. A desired illumination effect may also be ordered for live performances on stage or in any other type of setting.

Various conventional techniques for lighting in the film and television industries, and various illustrations of lighting equipment, are described, for example, in Lighting for Television and Film by Gerald Millerson (3rd ed. 1991), hereby incorporated herein by reference in its entirety, including pages 96-131 and 295-349 thereof, and in Professional Lighting Handbook by Verne Carlson (2nd ed. 1991), also hereby incorporated herein by reference in its entirety, including pages 15-40 thereof.

Since about 2002 photographic and video lighting has been transformed by the emergence of LED light sources as exemplified by the teachings of U.S. Pat. No. 6,749,310 the disclosure of which is incorporated herein by reference. These sources have radically reduced the power requirements needed to light situations just at a time when modern digital camera's sensitivity to light has also increased exponentially from film based times. Also at the same time the LED fixtures became completely dimmable as well. This convergence has allowed modern LED lights to be low enough in power to even run on batteries for many applications. These LED lights are based on white LEDs, most “white” LEDs in production today use a 450 nm-470 nm blue GaN (gallium nitride) LED covered by a yellowish phosphor coating usually made of cerium doped yttrium aluminum garnet (YAG:Ce) crystals which have been powdered and bound in a type of viscous adhesive. The LED chip emits blue light, part of which is converted to yellow by the YAG:Ce. The single crystal form of YAG:Ce is actually considered a scintillator rather than a phosphor. Since yellow light stimulates the red and green receptors of the eye, the resulting mix of blue and yellow light gives the appearance of white. There is great research and investment being made into the science of phosphors to try and provide all of the colors of the rainbow.

If a light source were to have the correct balance of all the visible colors it would have a Color Rendering Index (CRI) of 100, meaning 100%. Most modern LEDs that have their color balanced to “daylight” have a color rendering index between 60 and 84 which means depending on how well their phosphors have been engineered they have between 60% and 84% of the spectrum and balance of spectrum of what natural daylight has. There are no daylight LEDs that presently have CRI values much higher, those that do are generally very inefficient. One reason for this is that to get higher CRI requires more phosphors of differing kinds to be piled on the blue LED dye. Of course, a the thicker layer also blocks light from the phosphors closer to the dye and the little bit of blue light that reaches the outside doesn't have enough energy to excite those outside phosphors so there is a great loss of brightness in LEDs with this configuration. Thinner layers of phosphors give a much lower CRI but a much higher brightness.

It is a constant battle to maintain color temperature and color correction when manufacturing LEDs and these processes have variables that are constantly being adjusted to keep the LEDs between and within batches as consistent as possible. Often LEDs of the same nominal specification can vary in color temperature by several hundred degrees Kelvin temperature and several percentages of CRI. This is simply a present reality of the manufacturing process and the production yield of the parts.

When the CRI is 100, such as from direct sunlight, all of the colors of the photographic subject will look correct. As the CRI drops, certain colors will begin to appear dull or incorrect. The lower the CRI the more obvious the color inaccuracies become. One color that especially sensitive to the CRI of modern daylight balanced LEDs is red and colors near thereto in the color spectrum. One of the subjects that has a great deal of red in it and a wide variety of red colors is human skin. As a consequence, human skin color can render visually less than ideally under many of the lower CRI LEDS.

There have been widespread attempts to use “red/green/and blue” (RGB) LEDs to provide any color required for video capture. But although these sorts of LEDs may report CRIs as high as 50 or even higher, such reported CRI figures are since these three colors each have a very narrow wavelength. Some schemes have added a white LED but the only colored LED that really helps with any deficit of the white LED is the red and there needs to be several more colors to help. As a consequence, there have been a variety of other schemes that use different LED colors in conjunction with a white LED in order to fill some of the gaps of a white LED's CRI. However, when it is necessary to (e.g., using multiple dimming channels) these lights it is almost impossible to maintain a proper color balance and the control circuitry costs multiply by the number of additional colors used. As a consequence, the light is not homogenous and it is not very projectable due to the multiplicity of sources, multiple colors involved.

Another approach that has been tried with limited success involves the use of subtractive filters. Of course, these filters simply subtract a given color but they cannot create a color that is not already a part of the light emission spectrum. Thus, they are not effective for use in correcting the CRI of LEDs and, even if they were, the resulting efficiency would plunge so low as to make other light sources more efficient and viable than the task at hand.

Another problem with modern white LEDs is that they are too blue, which is a color temperature problem, and also too green, which is a color correction problem. Of course, once an LED is manufactured, these two properties are permanent part of the characteristics of this light. It would be advantageous to remove these colors in the green and blue bands when they are in excess.

What is needed is a technique for producing LEDS that efficiently produce the lower energy colors of red and yellow and orange that are needed for making the best possible light source for photographic and video capture with CRIs above 90.

There is an emerging technology called colloidal nanocrystals also known as quantum dots or Q dots for short. Seminal developments in the story of nanocrystal technology emerged in the early 1980s from the labs of Louis Brus at Bell Laboratories and of Alexander Efros and A.I. Ekimov of the Yoffe Institute in St. Petersburg (then Leningrad) in the former Soviet Union. Dr. Brus and his collaborators experimented with nanocrystal semiconductor materials and observed solutions of strikingly different colors made from the same substance. This work contributed to the understanding of the quantum confinement effect that helps explain the correlation between size and color for these nanocrystals. Conceptually, at least, these particles may be thought of as small clear spheres that are sized precisely to have the pseudo-prismatic effect of converting one light frequency to another.

One problem encountered in the use nanocrystals relates to their “tuneability” when they have been attempted to be used in an LED. It has been determined that they do not work well, or not the same, or they don't work at all if immersed into a clear epoxy or silicon of an LED. Another potential problem is that these Q dots cannot generally tolerate temperatures higher than 85° C. and the processes of making LEDs and fabricating them into useful arrays require temperatures greatly in excess of that.

Heretofore, as is well known in the film, television, video, motion picture, and photography arts, there has been a need for a system and method that provides a LED that has proper color balance and that does not suffer from the disadvantages of the prior art. Accordingly, it should now be recognized, as was recognized by the present inventors, that there exists, and has existed for some time, a very real need for a method of producing such an LED that would address and solve the above-described problems.

Before proceeding to a description of the present invention, however, it should be noted and remembered that the description of the invention which follows, together with the accompanying drawings, should not be construed as limiting the invention to the examples (or preferred embodiments) shown and described. This is so because those skilled in the art to which the invention pertains will be able to devise other forms of this invention within the ambit of the appended claims.

### SUMMARY OF THE INVENTION

Applicant incorporates herein fully by reference U.S. Pat. No. 7,429,117 as if set out in its entirety at this point.

A preferred embodiment of the inventive idea combines blue LED dye, phosphors, and Q dots (i.e., quantum dots) applied after fixture fabrication, window material, and the final element of a heat sink. Preferably the Q dots would be applied to the lens portion of the LED after all of the high temperature manufacturing processes had been complete. This application would preferably use a UV curable polymer as a base that is thin and viscous enough to not affect the geometry size of the Q dots and would act like permanent glue, holding the Q dots to the LED lens.

In another preferred embodiment, a clear filter with Q dots will be created and placed in the LED light path rather than applying them directly to the LED. This would use more of the expensive Q dot material but it would remove it from the potentially destructive heat of the LEDs. In some preferred embodiments, both the LED and the filter will be coated, with the Q dot coatings being either the same or different as the situation warrants.

A further preferred embodiment of the inventive idea would be to add a coating of Q dots to move the color temperature of a fixture of LEDs by, say, about 200° K. This coating would not necessarily have as a primary goal raising the CRI but, instead, it would be intended to move the color temperature or to change the color correction. This coating could be added after placement of an initial coating which was intended to improve the CRI, brightness, color temperature, color correction, etc., of the LEDs.

The foregoing has outlined in broad terms the more important features of the invention disclosed herein so that the detailed description that follows may be more clearly understood, and so that the contribution of the instant inventors to the art may be better appreciated. The instant invention is not limited in its application to the details of the construction and to the arrangements of the components set forth in the following description or illustrated in the drawings. Rather the invention is capable of other embodiments and of being practiced and carried out in various other ways not specifically enumerated herein. Additionally, the disclosure that follows is intended to apply to all alternatives, modifications and equivalents as may be included within the spirit and the scope of the invention as defined by the appended claims. Further, it should be understood that the phraseology and terminology employed herein are for the purpose of description and should not be regarded as limiting, unless the specification specifically so limits the invention.

### BRIEF DESCRIPTION OF THE DRAWINGS

Other objects and advantages of the invention will become apparent upon reading the following detailed description and upon reference to the drawings in which:

FIG. 1 contains an operating logic suitable for use with the instant invention.

FIG. 2 illustrates a preferred embodiment which uses a separate Q dot coated filter with an LED array.

### DETAILED DESCRIPTION OF THE PREFERRED EMBODIMENTS

Before describing preferred embodiment(s) of the present invention, an explanation is provided of several terms used herein.

The term “lamp element” is intended to refer to any controllable luminescent device, whether it be a light-emitting diode (“LED”), light-emitting electrochemical cell (“LEC”), a fluorescent lamp, an incandescent lamp, or any other type of artificial light source. The term “semiconductor light element” or “semiconductor light emitter” refers to any lamp element that is manufactured in whole or part using semiconductor techniques, and is intended to encompass at least light-emitting diodes (LEDs) light-emitting electrochemical cell (LECs), and organic light emitting diodes (OLEDs).

The term “light-emitting diode” or “LED” refers to a particular class of semiconductor devices that emit visible light when electric current passes through them, and includes both traditional low power versions (operating in, e.g., the 60 mW range) as well as high output versions such as those operating in the range of 1 Watt and up, though still typically lower in wattage than an incandescent bulb used in such application. Many different chemistries and techniques are used in the construction of LEDs. Aluminum indium gallium phosphide and other similar materials have been used, for example, to make warm colors such as red, orange, and amber. A few other examples are: indium gallium nitride (InGaN) for blue, InGaN with a phosphor coating for white, and Indium gallium arsenide with Indium phosphide for certain infrared colors. A relatively recent LED composition uses Indium gallium nitride (InGaN) with a phosphor coating. It should be understood that the foregoing LED material compositions are mentioned not by way of limitation, but merely as examples.

The term “light-emitting electrochemical cell” or LEC” refers to any of a class of light emitting optoelectronic devices comprising a polymer blend embedded between two electrodes, at least one of the two electrodes being transparent in nature. The polymeric blend may be made from a luminescent polymer, a sale, and an ion-conducting polymer, and various different colors are available. Further background regarding LECs may be found, for example, in the technical references D. H. ang et al, “New Luminescent Polymers for LEDs and LECs,” Macromolecular Symposia 125, 111 (1998), M. Gritsch et al, “Investigation of Local Ions Distributions in Polymer Based Light Emitting Cells,” Proc. Current Developments of Microelectronics, Bad Hofgastein (March 1999), and J. C. deMello et al, “The Electric Field Distribution in Polymer LECs,” Phys. Rev. Lett. 85(2), 421 (2000), all of which disclosures are hereby incorporated by reference as if set forth fully herein.

The term “color temperature” refers to the temperature at which a blackbody would need to emit radiant energy in order to produce a color that is generated by the radiant energy of a given source, such as a lamp or other light source. A few color temperatures are of particular note because they relate to the film and photographic arts. A color temperature in the range of 3200° Kelvin (or 3200° K) is sometimes referred to as “tungsten” or “tungsten balanced.” A color temperature of “tungsten” as used herein means a color temperature suitable for use with tungsten film, and, depending upon the particulars of the light source and the film in question, may generally cover the color temperature range anywhere from about 1000° Kelvin to about 4200° Kelvin. A color temperature in the range of 5500° Kelvin (or 5500° K) is sometimes referred to as “daylight” or “daylight balanced.” Because the color of daylight changes with season, as well as changes in altitude and atmosphere, among other things, the color temperature of “daylight” is a relative description and varies depending upon the conditions. A color temperature of “daylight” as used herein means a color temperature suitable for use with daylight film,and, depending upon the particulars of the light source and the film in question, may generally cover the color temperature range anywhere from about 4200° Kelvin to about 9500° Kelvin.

The lighting apparatuses of the present disclosure may utilize any number of lamp elements in a bi-color or other multi-color arrangement. Various embodiments of lighting apparatus as described herein utilize different color lamp elements in order to achieve, for example, increased versatility or other benefits in a single lighting mechanism. Among the various embodiments described herein are lamp apparatuses utilizing both daylight and tungsten lamp elements for providing illumination in a controllable ratio. Such apparatuses may find particular advantage in film-related applications where it can be important to match the color of lighting with a selected film type, such as daylight or tungsten. More importantly, such an arrangement would allow a user to match ambient light color.

In various embodiments as disclosed herein, a lighting apparatus is provided which utilizes two or more complementary colored lamp elements in order to achieve a variety of lighting combinations which, for example, may be particularly useful for providing illumination for film or other image capture applications. A particular example will be described with respect to a lighting apparatus using lamp elements of two different colors, herein referred to as a “bi-color” lighting apparatus. In a preferred embodiment, the bi-color lighting apparatus utilizes light elements of two different colors which are separated by a relatively small difference in their shift or color balance. When reference is made herein to light elements of two different colors, the light elements may, for example, include a first group which provide light output at a first color and a second group which provide light output at a second color, or else the light elements may all output light of a single color but selected ones of the light elements may be provided with colored LED lenses or filtering to generate the second color. In a preferred embodiment, as will be described, the bi-color lighting apparatus uses lamp elements having daylight and tungsten hues (for example, 5500° K and 3200° K color temperatures, respectively). Other bi-color combinations may also be used and, preferably, other combinations of colors which are closely in hue or otherwise complementary in nature.

One possible advantage of a bi-color lighting system as contained in the preferred embodiments below is the ability to more easily blend two similar colors (e.g., 5500 K and 3200 K color temperature hues), particularly when compared to a tri-color (e.g., RGB) lighting system that relies upon opposing or widely disparate colors. The blending process of two similar colors is not nearly as apparent to the eye, and more importantly in certain applications, is a more suitable lighting process for film or video image capture devices. In contrast, attempting to blend three primary or highly saturated (and nearly opposite colors) is much more apparent to the eye. In nature one may visually perceive the blending of bi-colors, for example, from an open sky blue in the shade, to the warmth of the direct light at sunset. Such colors are generally similar, yet not the same. Their proportion in relation to each other is a naturally occurring gradient in most every naturally lit situation. This difference is the basis of most photographic and motion picture lighting hues. These hues give viewers clues as to time of day, location and season. Allowing separate control of the two different color lamp elements (such as LEDs), through two separate circuit/dimmer controls or otherwise, provides the ability to easily adjust (e.g., cross-fade, cross-dim, etc.) between the two colors because they do not have significant color shifts when dimmed and blend in a visually pleasing manner, allowing the type of color gradients that occur in nature. In addition, virtually all still and motion picture film presently used in the industry is either tungsten or daylight balanced, such that various combinations of daylight and tungsten (including all one color) are well matched directly to the most commonly used film stocks. These features make the preferred lighting apparatus described herein particularly well suited for wide area still, video, and motion picture usage, especially as compared to RGB-based or other similar lighting apparatus. The above principles may also be extended to lighting systems using three or more lamp element colors.

Turning now to a discussion of the instant invention, there is an emerging technology called colloidal nanocrystals also known as quantum dots or Q dots for short. Conceptually, at least, these particles may be thought of as small clear spheres that are sized precisely to have the pseudo-prismatic effect of converting one light frequency to another.

One company that provides such materials is suitable for the present disclosure is NNCrystal Corp. 534 W. Research Center Blvd., Suite 254, Fayetteville Ark. 72701. By changing the particle size it will be possible to engineer the particular wavelength that is converted to another, predetermined, potentially more desirable, wavelength. By having several different types of these particles mixed together in an aggregate, a wide series of adjacent colors will potentially be created. Additional disclosure related to Q dots is included as Appendix 1, to U.S. Provisional Patent Application Ser. No. 61/530,206, filed on Sep. 1, 2011, the disclosure of which is incorporated by reference herein as if fully set out at this point.

Turning to a discussion of the theory underlying the instant invention, there is a direct, predictable relationship between the physical size of the quantum dot and the energy of the excitation (and, therefore, of the wavelength of emitted fluorescence). This property has been referred to as “tuneability”, and has been exploited in the development of multicolor assays.

The ability to precisely control the size of a quantum dot enables the manufacture to determine the wavelength of the emission, which in turn determines the color of light the human eye perceives. Quantum dots can therefore be tuned during production to emit any color of light desired. The smaller the dot, the closer it is to the blue end of the spectrum, and the larger the dot, the closer to the red end. Dots can even be tuned beyond visible light, into the infra-red or into the ultra-violet spectrum.

These quantum dots work at least in part by the diffraction difference (differences between the indices of refraction) between the solid plastic materials they are made from and the air. Thus, they do not work well, or not the same, or they don't work at all if immersed into a clear epoxy or silicon of an LED. This means that they cannot be placed like phosphors inside the LED without changing their size and, because of the blue dye, they don't do as good a job of making the high energy wavelengths such as blues, and greens.

Another potential problem is that these Q dots cannot generally tolerate temperatures higher than 85° C. and the processes of making LEDs and fabricating them into useful arrays require temperatures greatly in excess of that. There is also the problem that LEDs can operate in excess of 85° C. so even conducted heat of regular use could potentially destroy the Q dots.

One blend of Q dots can add about 35 nanometers (nm) of color in the longer wavelength regions. Generally the spectral areas most in color deficit are from 570-750 nm so between 2 and 4 concurrent set of Q dots could fill all of the deficits by borrowing energy from the excess green and blue spectrums of the LED's light.

Turning now to a discussion of a first preferred embodiment of the inventive idea, the instant invention combines blue LED dye, phosphors, and Q dots applied after fixture fabrication, window material, and the final element of a heat sink. The Q dots would be applied to the lens portion of the LED after all of the high temperature processes had been complete. The Q dots may be deposed in a medium to assist in their application to an LED. This application will preferably use a UV curable polymer medium that is thin and viscous enough to not affect the geometry size of the Q dots and it would act like permanent glue, holding the Q dots to the LED lens.

Traditionally through-hole LEDs are mounted in copper pads on a printed circuit board (PCB) but the inventive idea uses PCBs covered in copper over the majority of its surface on both sides in order to remove the heat from the LEDs, thus protecting the heat sensitive Q dots. If the LEDs were not through hole they would be mounted to a traditional metal or thermally conductive plastic heat sink. If they were surface mount LEDs they would use copper that covers the most of the PCB, similar to the through-hole LEDs of the inventive idea. This application would be to improve the CRI, brightness, color temperature, or color correction of the LEDs.

A further preferred embodiment of the inventive idea would be to coat a clear filter with Q dots and place it in the LED light path rather than apply them directly to the LED. This would require the use of more of the expensive Q dot material but it would remove it from the potentially destructive heat of the LEDs. This filter could be directly adjacent to the LEDs or on the inside of the faceplate or secondary lens or it could be external and added and removed manually.

Another preferred embodiment of the inventive idea would be to add a coating of Q dots to move the color temperature of a fixture of LEDs by 200K. This coating would not have as its primary goal raising the CRI but instead to move the color temperature or to change the color correction in anon-subtractive way. This coating would help to narrow the process control of the color, to narrow the color bin, or to narrow the yield of the color of the LEDs. This coating could be added after an initial coating that was designed to improve the CRI, brightness, color temperature, or color correction of the LEDs.

In some preferred embodiments the coating would be sprayed on the LED. In other preferred embodiments the LED might be dipped in a solution that contains the Q dots. Either way, the goal would be to apply the Q dots to at least a portion of the light-transmitting surface of the LED, affixed to a filter that sits between the LEDs and the photographic or video subject, or apply the Q dots to both surfaces. Of course, in some instances it might be necessary or desirable to apply different Q dots to the LEDs and the filter in order that the resulting light spectrum is shaped as desired.

Additionally, in some embodiments the Q dots might be applied after the wave soldering step that is conventionally utilized in the manufacture of LED boards. Since it is customary to wash the LED boards after wave soldering to get the flux off of the board the coating of this aspect of the instant invention might be applied in conjunction with or at, for example, a post-wash drying station.

In some embodiments, the coating might be applied to correct the light spectrum properties of a collection of LEDs taken as a whole. That is, since it is customary to mount multiple LEDs to a board, and since each LED potentially will have a different light spectrum it may be more economical to correct the array as a whole rather than individually correct each LED. Thus, what would be important in that case would be the composite light spectrum for the entire board. One preferred approach would be to assemble an array of LEDs and then determine the spectrum of the array. Then, based on that spectrum, choose the coating from, for example, a number of different predetermined coatings that best correct its spectrum. This would, of course, eliminate the necessity of creating a custom batch of Q dots for each LED array at the possible cost of applying a somewhat less than optimal coating. Of course, this method would likely work best where the LEDs were at least somewhat consistent and/or had been presorted into bins of LEDs with similar spectra.

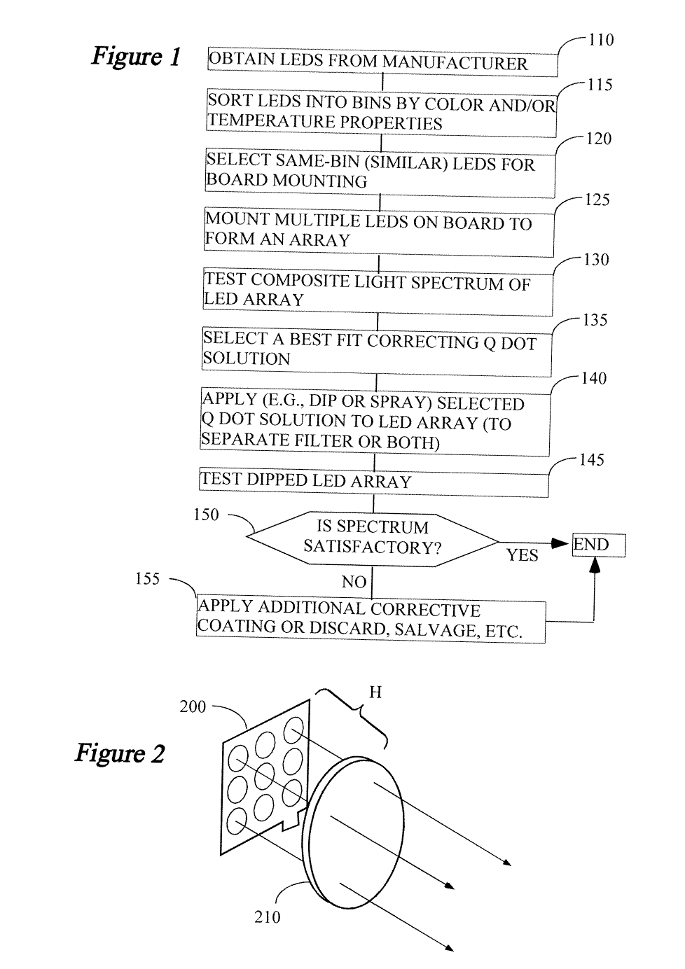

FIG. 1 summarizes some key aspects of the approach described above. As is generally indicated in this figure, in some preferred embodiments of a manufacturing process, LEDs will be received from the manufacturer (step 110) and, even though these LEDs might nominally have the same emission properties, there will typically be subtle (and not so subtle) difference between them even if they are produced in the same manufacturing run. Thus, the preferred approach is to sort each batch of LEDs into bins at least roughly according to their actual color and/or temperature properties (step 115).

Next, some number of LEDs will be selected from the same bin for purposes of board mounting (step 120). Obviously, one advantage of advanced sorting/binning the LEDS is that the assembled board should have LEDs that have at least approximately the same spectra.

As a next preferred step 125, the selected LEDs will be mounted on a board in an array configuration. Next, and preferably, the mounted LED array will be activated and the composite light spectrum of the board will be assessed (step 130) at least to the extent of determining the light frequencies that are deficient and excessive. Next, and preferably, a Q dot solution that at least approximately provides some correction for the spectral deficiencies of the array LED spectrum will be selected (step 135). As has been discussed previously, in some preferred embodiments there will be some number of preconfigured Q dot solutions that are designed to correct common deficiencies in the light spectra of these LED arrays. The one that is chosen will preferably be the best single correcting solution. That being said, in some instances it might be desirable or necessary to coat with two or more different solutions.

As has also been indicated previously, the selected Q dot solution will be applied, preferably either directly to the LEDs individually or to a separate filter (step 140). Next, and preferably, the dipped (or sprayed, etc.) LED array will be assessed again to determine its light spectrum (step 145). In the event that the Q dot solution has been applied to a separate filter, the light passing through that filter will preferably be tested.

In the event that the resulting spectrum is satisfactory (the “YES” branch of decision item 150), this portion of the instant manufacturing process will be ended. If the resulting spectrum that it is not satisfactory (i.e., the “NO” branch of decision item 150), an additional corrective coating might be applied to the LED array or to the filter. In the event that there is no readily available alternative Q dot solution that could be applied, or if the LED spectrum of the array is simply not correctable or does not merit correction, the resulting LED board will likely be discarded, salvaged, etc. (step 155), and the instant manufacturing portion of the instant invention will then terminate.

FIG. 2 contains an illustration of how a filter coated with Q dots might be used in connection with an LED array 200. In a preferred embodiment, the filter 210 will be positioned some distance, H, away from the LEDs so as to reduce the heating thereof. In some embodiments H might be ½″ or so but those of ordinary skill in the art will readily be able to position the filter appropriately so that it captures the light from the LED array 200 without causing the temperature of the Q dots on the filter to exceed about 85° C. or whatever temperature is problematic for the Q dots. In some preferred embodiments, the filter will have a general appearance similar to that of a diffusion filter. Again, and has been discussed previously, the Q dot coating that has been applied to the filter will preferably be one that is designed to correct the composite light spectrum of the LEDs considered as an array to the extent possible.

By way of summary, one embodiment of the instant invention is designed to use Q dots or a similar nanocrystal to transfer, for example, LED light energy in one band to another, e.g., the blue band (which tends to be excessive) might be transferred to the red band where such LEDs tend to be deficient. This approach would tend to balance the overall spectrum of the LED without a corresponding loss in brightness as would be the case where the light from the LED was passed through a conventional filter.

This approach means that, among other things, lower quality LEDs could be purchased with the idea that their spectra could thereafter be shaped to be closer to that of an ideal spectrum using Q dots. Further, even with higher quality LEDs, the instant invention will provide improved lighting for image capture purposes.

Although a polymer (including plastics) is the preferred material in which to embed the Q dots, those of ordinary skill in the art will readily be able to device other materials that would be suitable for use. Preferably, though, the carrier material will be largely transparent to visible light or have a transmission spectrum that complements that of the LED to which it is affixed.

Thus, the present invention is well adapted to carry out the objects and attain the ends and advantages mentioned above as well as those inherent therein. While the inventive device has been described and illustrated herein by reference to certain preferred embodiments in relation to the drawings attached thereto, various changes and further modifications, apart from those shown or suggested herein, may be made therein by those skilled in the art, without departing from the spirit of the inventive concept the scope of which is to be determined by the following claims.

While preferred embodiments of the invention have been described herein, many variations are possible which remain within the concept and scope of the invention. Such variations would become clear to one of ordinary skill in the art after inspection of the specification and the drawings. The invention therefore is not to be restricted except within the spirit and scope of any appended claims.

What is claimed:

1. An LED capable of emitting light at a wavelength including a lens, comprising the lens, including a plurality of quantum dots applied thereon; said quantum dots being sized so as to change the wavelength of the light emitted from said LED.

2. The LED of claim 1 wherein said plurality of quantum dots are sized so as to change the wavelength of the light emitted from said LED to a predetermined wavelength.

3. The LED of claim 1 wherein said quantum dots vary in size.

4. The LED of claim 1 wherein said quantum dots are affixed to the lens using a UV curable polymer.

5. A process for changing the wavelength of light emitted from an LED comprising:
applying a plurality of quantum dots to the LED.

6. The process of claim 5 wherein the plurality of quantum dots are applied to a plurality of LEDs disposed in an array.

7. The process of claim 6 wherein the quantum dots are applied to an array of LEDs which are mounted to a printed circuit board.

8. The process of claim 6 wherein the light emitted from each LED constituting said plurality of LEDs include a similar spectra.

9. The process of claim 6 wherein the light emitted from each LED constituting said plurality of LEDs includes similar temperature properties.

10. The process of claim 7 wherein the LEDs constituting said plurality of LEDs are selected for their color and for temperature properties.

11. The process of claim 10 wherein said plurality of quantum dots are sized so as to change the wavelength of the light emitted from said array of LEDs to predetermined wavelength.

12. The process of claim 10 wherein each said LED in said array includes a lens and said plurality of quantum dots are applied to said lens.

13. The process of claim 12 wherein said plurality of quantum dots are dispersed in a medium.

14. The process of claim 13 wherein said medium is a UV curable polymer.

15. The process of claim 13 wherein said medium is sprayed onto said lens.

16. The process of claim 13 wherein said lens is dipped into said medium.

17. The process of claim 10 wherein said plurality of quantum dots are applied to a filter.

18. The process of claim 17 wherein said filter is capable of being placed over said array.

19. The process of claim 13 wherein said lens constituting a light transmission surface and said plurality of quantum dots are applied to at least a portion of said light transmission surface.

20. The process of claim 10 wherein said quantum dots are applied to a filter capable of being placed over said array.
